(19) United States
(12) Patent Application Publication
(10) Pub. No.: US 2008/0116200 A1
(43) Pub. Date: May 22, 2008

(54) METHOD FOR MANUFACTURING A HONEYCOMB STRUCTURE, HONEYCOMB MOLDED BODY RECEIVING APPARATUS, HONEYCOMB MOLDED BODY TAKING-OUT APPARATUS

(75) Inventors: Tsuyoshi Kawai, Ibi-gun (JP); Kenichiro Kasai, Ibi-gun (JP); Kazuya Naruse, Courtenay (FR)

Correspondence Address: DITTHAVONG MORI & STEINER, P.C., 918 Prince St., Alexandria, VA, 22314, US

(73) Assignee: IBIDEN CO., LTD., Ogaki (JP)

(21) Appl. No.: 11/931,935

(22) Filed: Oct. 31, 2007

Related U.S. Application Data
(63) Continuation of application No. PCT/JP2006/309265, filed on May 8, 2006.

(51) Int. Cl. C04B 35/64; B65D 8/18; H01L 21/68; B65D 90/12

(52) U.S. Cl. 220/4.21; 264/630; 414/783; 220/628

(57) ABSTRACT

A method for manufacturing a honeycomb structure includes producing a pillar-shaped honeycomb molded body in which a plurality of cells are placed in parallel with one another in a longitudinal direction with a cell wall therebetween by molding a ceramic raw material; and producing a honeycomb fired body by carrying out a single or a plurality of treatments including at least a firing treatment on the honeycomb molded body. The method further includes temporarily storing the treated honeycomb molded body on which the single or plurality of treatments have been carried out in a molded body storage container; taking out the treated honeycomb molded body placed in the molded body storage container from the molded body storage container; and conveying the taken-out honeycomb molded body to a subsequent process.

### CROSS-REFERENCE TO RELATED APPLICATIONS

This application is a continuation application of PCT/JP2006/309265 filed on May 8, 2006. The contents of these applications are incorporated herein by reference in their entirety.

### BACKGROUND OF THE INVENTION

1. Field of the Invention

The present invention relates to a method for manufacturing a honeycomb structure, a honeycomb molded body receiving apparatus, and a honeycomb molded body taking-out apparatus.

2. Discussion of the Background

Particulates such as soot contained in the exhaust gas discharged by the internal combustion engines of vehicles such as busses, trucks, and construction equipment and the like, have become a problem of recent years, in that they cause harm to the environment and the human body. To remedy this, there have been proposed various honeycomb structures including porous ceramics, which serve as filters capable of capturing particulates in exhaust gases to purify the exhaust gases.

Conventionally, when manufacturing a honeycomb structure, first, ceramic powder, binder, and a liquid dispersal medium and the like are mixed to prepare a moist mixture. The moist mixture is then extrusion molded continuously according to use of a die, and the extruded molded body is then cut to a prescribed length. Thus a rectangular pillar-shaped honeycomb molded body is manufactured.

Next, the honeycomb molded body attained above is dried using a microwave drying or a hot-air drying, and afterward, prescribed cells are sealed with a plug in order to achieve a state where one of the end portion of the cells being sealed. After the sealed state has been achieved, a degreasing treatment and a firing treatment are carried out thereon, thus manufacturing the honeycomb fired body.

After this, a sealing material paste is coated onto the sides of the honeycomb fired body, and an aggregated body of honeycomb fired bodies in which a multitude of honeycomb fired bodies are combined with one another by interposing a sealing material layer (adhesive layer). Next, cutting processing using a cutting machine or the like is carried out on the aggregated body of honeycomb fired bodies in order to produce a honeycomb block of a prescribed form, such as cylindrical form, cylindroid form or the like. Finally, sealing material paste is coated over the outer circumference of the honeycomb block to form a sealing material layer (a coat layer), thereby completing the manufacturing of the honeycomb structure (for example, see Japanese Unexamined Patent Application Publication 2002-126427 A).

The contents of Japanese Unexamined Patent Application Publication 2002-126427 A are incorporated herein by reference in their entirety.

### SUMMARY OF THE INVENTION

A method for manufacturing a honeycomb structure according to the present invention having a honeycomb fired body includes producing a pillar-shaped honeycomb molded body in which a plurality of cells are placed in parallel with one another in a longitudinal direction with a cell wall therebetween by molding a ceramic raw material; and producing a honeycomb fired body by carrying out a single or a plurality of treatments including at least a firing treatment on the honeycomb molded body. The method further includes temporarily storing the treated honeycomb molded body on which the single or plurality of treatments have been are carried out in a molded body storage container; taking out the treated honeycomb molded body placed in the molded body storage container from the molded body storage container; and conveying the taken-out honeycomb molded body to a subsequent process.

The method for manufacturing a honeycomb structure according to the present invention desirably further includes carrying out at least a drying treatment and a firing treatment on the honeycomb molded body after producing the honeycomb molded body. The treated honeycomb molded body stored temporarily is a honeycomb molded body on which the drying treatment and/or the firing treatment has been carried out.

The method for manufacturing a honeycomb structure according to the present invention desirably further includes carrying out at least a drying treatment, an opening-sealing treatment and a firing treatment on the honeycomb molded body after having produced the honeycomb molded body. The treated honeycomb molded body stored temporarily is a honeycomb molded body on which at least one of the drying treatment, the opening-sealing treatment and the firing treatment has been carried out.

In the method for manufacturing a honeycomb structure according to the present invention, the time period of temporarily storing the honeycomb molded body on which at least one of the drying treatment, the opening-sealing treatment and the firing treatment has been carried out is desirably about one month.

A honeycomb molded body receiving apparatus of the present invention is used to place the treated honeycomb molded body into the molded body storage container in the method for manufacturing a honeycomb structure according to the present invention. The honeycomb molded body receiving apparatus includes a molded body pre-storage container induction portion configured to stack and hold an empty molded body storage container; a first molded body storage container movement mechanism configured to move the empty molded body storage container in the upward/downward direction and/or the horizontal direction to situate the molded body storage container in a prescribed location; a robotic arm configured to lift up and move the treated honeycomb molded body situated atop a conveyer portion using a holding portion, and place the treated honeycomb molded body inside of the empty molded body storage container situated in the prescribed location; a second molded body storage container movement mechanism configured to stack the molded body storage container having the treated honeycomb molded body placed therein onto a molded body storage container having another treated honeycomb molded body placed therein; and a molded body post-storage container taking-out portion configured to stack and hold the molded body storage container having the treated honeycomb molded body placed therein.

In the honeycomb molded body receiving apparatus according to the present invention, the treated honeycomb molded body to be temporarily stored is desirably a honeycomb molded body on which the drying treatment and/or the firing treatment has been carried out, and the treated honeycomb molded body to be temporarily stored is desirably a honeycomb molded body on which at least one of the drying treatment, the opening-sealing treatment and the firing treatment has been carried out.

In the honeycomb molded body receiving apparatus according to the present invention, a location where the empty molded body storage container is to be situated, when placing the treated honeycomb molded body therein, is desirably at the upper side with respect to a location where the molded body storage container having the treated honeycomb molded body placed therein is to be stacked.

In the honeycomb molded body receiving apparatus according to the present invention, a location where the empty molded body storage container is to be situated, when placing the treated honeycomb molded body therein, is desirably at the upper side with respect to a location where stacked the empty molded body storage container is held.

In the honeycomb molded body receiving apparatus according to the present invention, the molded body storage container has a rectangular shape when viewed from the top, and is desirably provided with gaps on the portion of the side faces corresponding to the short sides thereof, in order to allow insertion of a member configured to lift up another molded body storage container stacked on the top of the molded body storage container when the molded body storage container is stacked.

The honeycomb molded body receiving apparatus according to the present invention further includes a storage container lifting apparatus. The storage container lifting apparatus, desirably disposed on both sides sandwiching the path of the molded body storage container, includes a lifting portion configured to directly lift up the molded body storage container, an air cylinder for the purpose of moving the lifting portion in the upward and downward directions, and a platform portion configured to support the air cylinder, and the air cylinder is disposed in the lifting portion, the air cylinder being desirably configured in a manner enabling the lifting portion to move in the horizontal direction.

The honeycomb molded body receiving apparatus according to the present invention further includes a storage container support apparatus. The storage container support apparatus, two units of which being desirably disposed on both sides of a region through which the molded body storage container moves, includes a storage container support portion which is for the purpose of supporting the molded body storage container moved thereto; an air cylinder which is for the purpose of moving the storage container support portion in the direction nearing the molded body storage container when supporting the molded body storage container, and alternately moving the storage container support portion in the direction away from the molded body storage container when releasing the supported molded body storage container; and a cylinder support portion configured to support the air cylinder.

A honeycomb molded body taking-out apparatus of the present invention is used to take out the treated honeycomb molded body from the molded body storage container in the method for manufacturing a honeycomb structure according to the present invention. The honeycomb molded body taking-out apparatus includes a molded body post-storage container induction portion configured to stack and hold the molded body storage container having the treated honeycomb molded body placed therein; a third molded body storage container movement mechanism configured to move the molded body storage container having the treated honeycomb molded body placed therein in the upward/downward direction and/or the horizontal direction to situate the molded body storage container in a prescribed location; a robotic arm configured to lift up and move the treated honeycomb molded body placed in the molded body storage container by using a holding portion, and place the treated honeycomb molded body atop a conveyer portion; a fourth molded body storage container movement mechanism configured to stack the empty molded body storage container having the treated honeycomb molded body taken out therefrom onto another empty molded body storage container; and a molded body pre-storage container taking-out portion configured to stack and hold the empty molded body storage container.

In the honeycomb molded body taking-out apparatus according to the present invention, the treated honeycomb molded body to be temporarily stored is desirably a honeycomb molded body on which the drying treatment and/or the firing treatment has been carried out, and the treated honeycomb molded body to be temporarily stored is desirably a honeycomb molded body on which at least one of the drying treatment, the opening-sealing treatment and the firing treatment has been carried out.

In the honeycomb molded body taking-out apparatus according to the present invention, a location where the molded body storage container is to be situated, when lifting up the treated honeycomb molded body by using the holding portion, is desirably at the upper side with respect to a location where the empty molded body storage container is to be stacked.

Further, in the honeycomb molded body taking-out apparatus according to the present invention, a location where the molded body storage container is to be situated, when lifting up the treated honeycomb molded body by using a holding portion, is desirably at the upper side with respect to a location where a stacked molded body storage container having the treated honeycomb molded body placed therein is to be held.

In the honeycomb molded body taking-out apparatus according to the present invention, the molded body storage container has a rectangular shape when viewed from the top, and is desirably provided with gaps on the portion of the side faces corresponding to the short sides thereof, in order to allow insertion of a member configured to lift up another molded body storage container stacked on the top of the molded body storage container when the molded body storage container is stacked.

The honeycomb molded body taking-out apparatus according to the present invention, further includes a storage container lifting apparatus. The storage container lifting apparatus, desirably disposed on both sides sandwiching the path of the molded body storage container, includes a lifting portion configured to directly lift up the molded body storage container, an air cylinder for the purpose of moving the lifting portion in the upward and downward directions, and a platform portion configured to support the air cylinder, and the air cylinder is disposed in the lifting portion, the air cylinder being desirably configured in a manner enabling the lifting portion to move in the horizontal direction.

The honeycomb molded body taking-out apparatus according to the present invention further includes a storage container support apparatus. The storage container support apparatus, two units of which being desirably disposed on both sides of a region through which the molded body storage container moves, includes a storage container support portion which is for the purpose of supporting the molded body storage container moved thereto; an air cylinder which is for the purpose of moving the storage container support portion in the direction nearing the molded body storage container when supporting the molded body storage container, and alternately moving the storage container support portion in the direction away from the molded body storage container when releasing the supported molded body storage container; and a cylinder support portion configured to support the air cylinder.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings.

FIG. 1 is a perspective view schematically showing an example of a honeycomb structure according to the embodiments of the present invention.

FIG. 2A is a perspective view schematically showing a honeycomb fired body including a honeycomb structure according to the embodiments of the present invention, and FIG. 2B is an A-A line cross-sectional view of FIG. 2A.

FIG. 3A is a frontal view schematically showing a honeycomb molded body receiving apparatus according to the embodiments of the present invention; FIG. 3B is a frontal view showing a storage container lifting apparatus including the honeycomb molded body receiving apparatus shown in FIG. 3A; FIG. 3C is a side view of the storage container lifting apparatus shown in FIG. 3B; FIG. 3D is a plan view of a storage container support apparatus including the honeycomb molded body receiving apparatus shown in FIG. 3A; and FIG. 3E is a side view of the storage container support apparatus shown in FIG. 3D.

FIG. 4 is a plan view of the honeycomb molded body receiving apparatus shown in FIG. 3A.

FIG. 5 is a side view of the honeycomb molded body receiving apparatus shown in FIG. 3A.

FIG. 6 is an enlarged perspective view showing a close up of the storage container lifting apparatus and a storage container moving apparatus including the honeycomb molded body receiving apparatus shown in FIG. 4.

FIGS. 7A and 7B are descriptive figures for the purpose of describing another configuration of the honeycomb molded body receiving apparatus according to the embodiments of the present invention.

### DESCRIPTION OF THE EMBODIMENTS

The embodiments will now be described with reference to the accompanying drawings, wherein like reference numerals designate corresponding or identical elements throughout the various drawings.

The method for manufacturing a honeycomb structure including a honeycomb fired body according to the embodiment of the present invention includes producing a pillar-shaped honeycomb molded body in which a plurality of cells are placed in parallel with one another in a longitudinal direction with a cell wall therebetween by molding a ceramic raw material; and producing a honeycomb fired body by carrying out a single or a plurality of treatments including at least a firing treatment on the honeycomb molded body. The method further includes temporarily storing a treated honeycomb molded body on which the single or plurality of treatments have been carried out in a molded body storage container; taking out the treated honeycomb molded body placed in the molded body storage container from the molded body storage container; and conveying the taken-out honeycomb molded body to a subsequent process.

In the present specification, the shape indicated by the word “pillar” refers to any desired shape of a pillar including a round pillar, an oval pillar, a polygonal pillar and the like.

With the method for manufacturing a honeycomb structure according to the embodiment of the present invention, since after placing a treated honeycomb molded body into a molded body storage container and temporarily storing it, the treated honeycomb molded body placed in the molded body storage container is taken out and placed atop a conveyer portion headed toward a subsequent process, it is possible to compartmentalize the continuous production process without any decrease in productivity. Thus, even if a trouble arises in any process of a plurality of processes, it is possible to run other processes as usual. As a result, it is possible to avoid the inconvenience of having to discard an immature product due to an arising trouble.

Also, as described above, by compartmentalizing the continuous production process, it is possible to adjust the amount of production as well as to produce and store treated honeycomb molded bodies.

A honeycomb molded body receiving apparatus according to the embodiment of the present invention is used when placing the treated honeycomb molded body into the molded body storage container in the method for manufacturing a honeycomb structure according to the embodiment of the present invention. The honeycomb molded body receiving apparatus includes a molded body pre-storage container induction portion configured to stack and hold an empty molded body storage container; a first molded body storage container movement mechanism configured to move the empty molded body storage container in the upward/downward direction and/or the horizontal direction to situate the molded body storage container in a prescribed location; a robotic arm configured to lift up and move the treated honeycomb molded body situated on a conveyer portion using a holding portion, and place the treated honeycomb molded body inside of the empty molded body storage container situated in the prescribed location; a second molded body storage container movement mechanism configured to stack the molded body storage container having the treated honeycomb molded body placed therein onto a molded body storage container having another treated honeycomb molded body placed therein; and a molded body post-storage container taking-out portion configured to stack and hold the molded body storage container having the treated honeycomb molded body placed therein.

Since the honeycomb molded body receiving apparatus according to the embodiment of the present invention is configured to automatically carry out a process of placing the treated honeycomb molded body into the molded body storage container, it is possible to efficiently carry out placement of the treated honeycomb molded body into the molded body storage container without manual effort (manual working).

A honeycomb molded body taking-out apparatus according to the embodiment of the present invention is used when taking out the treated honeycomb molded body from the molded body storage container in the method for manufacturing a honeycomb structure according to the embodiment of the present invention. The honeycomb molded body taking-out apparatus includes a molded body post-storage container induction portion configured to stack and hold the molded body storage container having the treated honeycomb molded body placed therein; a third molded body storage container movement mechanism configured to move the molded body storage container having the treated honeycomb molded body placed therein in the upward/downward direction and/or the horizontal direction to situate the molded body storage container in a prescribed location; a robotic arm configured to lift up and move the treated honeycomb molded body placed in the molded body storage container by using a holding portion, and place the treated honeycomb molded body on a conveyer portion; a fourth molded body storage container movement mechanism configured to stack the empty molded body storage container having the treated honeycomb molded body taken out therefrom onto another empty molded body storage container; and a molded body pre-storage container taking-out portion configured to stack and hold the empty molded body storage container.

Since the honeycomb molded body taking-out apparatus according to the embodiment of the present invention is configured to automatically carry out a process of taking out the treated honeycomb molded body from within the molded body storage container, it is possible to efficiently carry out taking out of the treated honeycomb molded body from within the molded body storage container without manual effort (manual working).

First, the method for manufacturing a honeycomb structure according to the embodiment of present invention will be described.

In the method for manufacturing a honeycomb structure according to the embodiment of the present invention, a plurality of treatment processes are carried out in succession.

In general, (1) a honeycomb molded body production process in which a moist mixture is prepared by mixing and kneading raw material and then the moist mixture is extrusion molded and cut to a prescribed length, (2) a honeycomb molded body drying process in which a drying treatment is carried out on the honeycomb molded body, (3) a honeycomb molded body opening-sealing process in which an opening-sealing treatment of filling a plug material paste into an end portion of the cells of the dried honeycomb molded body is carried out (also referred to as honeycomb molded body plugging process), (4) a honeycomb molded body degreasing process in which a degreasing treatment is carried out on the honeycomb molded body, (5) a honeycomb molded body firing process in which a firing treatment is carried out on the degreased honeycomb molded body thereby producing a honeycomb fired body, (6) a honeycomb aggregated body production process in which an aggregated body of honeycomb fired bodies is produced by combining a plurality of honeycomb fired bodies with one another by interposing a sealing material layer (an adhesive layer), (7) a honeycomb block production process in which a honeycomb block of a prescribed shape is produced by machining on the outer circumference of the honeycomb aggregated body, (8) a coat layer forming process in which a sealing material layer (a coat layer) is formed over the circumference of the honeycomb block, and processes of the like, are carried out in succession to produce the honeycomb structure.

It should be noted that, in the method for manufacturing a honeycomb structure according to the embodiment of the present invention, it is not necessarily required to carry out all of the above-mentioned processes (1) to (8), as it is acceptable to carry out only those processes necessary according to the design of the honeycomb structure.

Specifically, for example, although it would be necessary to carry out (3) the honeycomb molded body opening-sealing process (honeycomb molded body plugging process) in a case of producing a honeycomb structure intended to function as a filter, in a case of producing a honeycomb structure intended to function as a catalyst supporting carrier, however, it is not necessary to carry out (3) the honeycomb molded body opening-sealing process (honeycomb molded body plugging process).

Again, for example, although it would be necessary to carry out (6) the honeycomb aggregated body production process in a case of producing an aggregated honeycomb structure, in a case of producing an integral honeycomb structure, however, it is not necessary to carry out (6) the honeycomb aggregated body production process. The distinction between the aggregated honeycomb structure and the integral honeycomb structure will be described later.

In the method for manufacturing a honeycomb structure according to the embodiment of the present invention, a treated honeycomb molded body attained through any of the above-mentioned processes (2) to (8) and placed on a conveyer portion to be conveyed to a subsequent process, is stored once temporarily in a molded body storage container, and afterward, is placed atop a conveyer portion to a subsequent process.

It should be noted that, in the present description, the term “treated honeycomb molded body” refers to not only a honeycomb molded body on which a drying treatment and a degreasing treatment have been carried out, but also a honeycomb molded body on which various treatments such as an opening-sealing treatment have been carried out. Further, a honeycomb aggregated body in which a plurality of honeycomb fired bodies produced from honeycomb molded bodies are combined with one another, and a honeycomb aggregated body whose external shape has been machined are also included in the treated honeycomb molded body.

Also, in the method for manufacturing a honeycomb structure according to the embodiment of the present invention, when a treated honeycomb molded body is stored temporarily, the time period of storage is not particularly limited as long as it is to the extent that the physical properties of the treated honeycomb molded body do not change.

For example, it is desirable for the time period of storage to be about one month or less in a case of temporarily storing a honeycomb molded body on which a drying treatment or has been carried out or a honeycomb molded body on which an opening-sealing treatment has been carried out. Also, in a case of storing a honeycomb molded body on which a firing treatment has been carried out, for example, the time period of storage is not limited.

The molded body storage container used in the above-mentioned method for manufacturing a honeycomb structure according to the embodiment is not particularly limited as long as it is able to have a treated honeycomb molded body being the storage target placed therein. The size of the molded body storage container may be arbitrarily selected. It is desirable, however, that the size of the above-mentioned molded body storage container be the one able to hold a plurality of treated honeycomb molded bodies simultaneously.

Also, the material of the above-mentioned molded body storage container is not particularly limited.

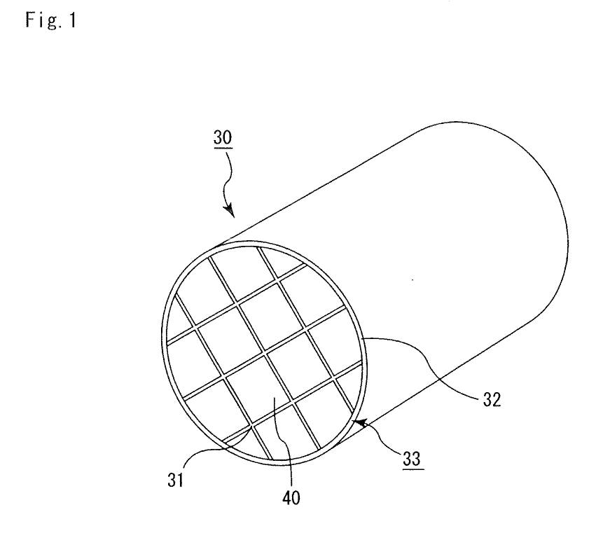

Also, concrete examples of the honeycomb structure produced with the method for manufacturing a honeycomb structure according to the embodiment of the present invention include the honeycomb structure (See FIG. 1) produced by firing a pillar shaped honeycomb molded body in which a plurality of cells are placed in parallel with one another in a longitudinal direction with a cell wall therebetween and then combining a plurality of such attained honeycomb fired bodies with one another by interposing a sealing material layer (an adhesive layer), the pillar-shaped honeycomb structure made of a single honeycomb sintered body attained by firing a honeycomb molded body in which a plurality of cells are placed in parallel with one another in a longitudinal direction with a cell wall therebetween, and the like.

In the present description, the former honeycomb structure in which a plurality of honeycomb fired bodies are combined with one another by interposing a sealing material layer (an adhesive layer) is referred to as an “aggregated honeycomb structure”, while the latter pillar-shaped honeycomb structure made of a single honeycomb sintered body is referred to as an “integral honeycomb structure”.

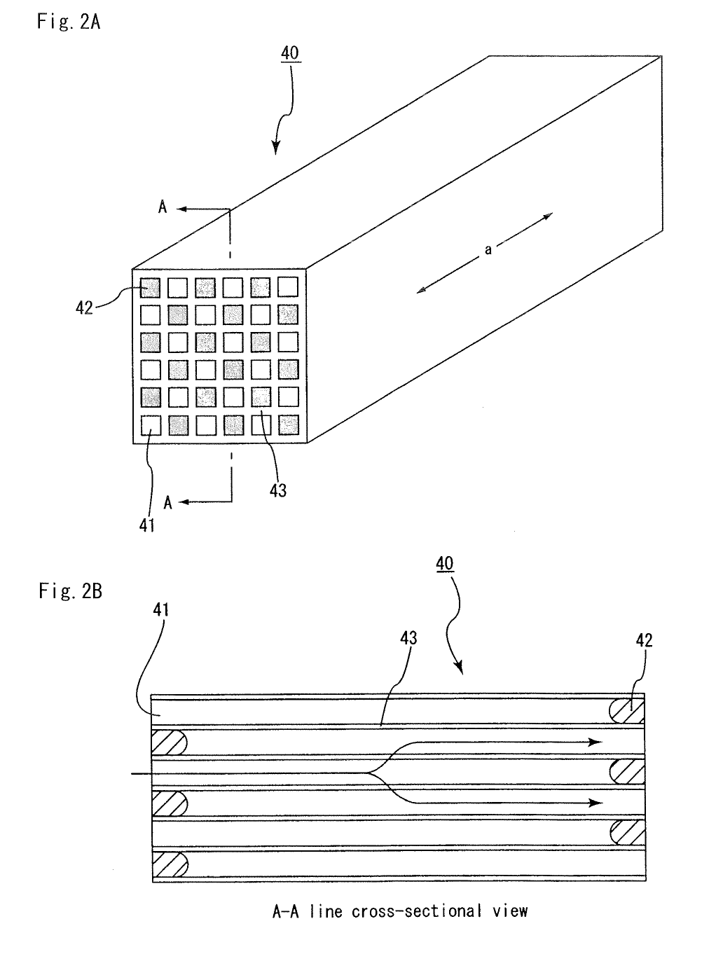

FIG. 1 is a perspective view schematically showing an example of a honeycomb structure. FIG. 2A is a perspective view schematically showing a honeycomb fired body that includes the above-mentioned honeycomb structure, while FIG. 2B is an A-A cross-sectional view of the honeycomb fired body.

In a honeycomb structure 30, a plurality of honeycomb fired bodies 40, of the kind shown in FIGS. 2A and 2B, are combined with one another by interposing a sealing material layer (an adhesive layer) 31 to form a honeycomb block 33, and a sealing material layer (a coat layer) 32 is formed there over the outer periphery of the honeycomb block 33.

Further, in the honeycomb fired body 40, as shown in FIG. 2A and FIG. 2B, a multitude of cells 41 are placed in parallel with one another in the longitudinal direction (see a in FIG. 2A), and cell walls 43, which separate the cells 41, function as filters.

More specifically, as shown in FIG. 2B, the end portion on either the inlet side or the outlet side of the cells 41 formed in the honeycomb fired body 40 are sealed with an opening-sealing layer 42. The exhaust gas flowing into one of the cells 41 passes through the cell walls 43 separating the cells 41 without fail, and flow out through another cell 41. When the exhaust gas passes through the cell wall 43, particulates contained within the exhaust gas are captured by the cell wall 43, thereby purifying the exhaust gas.

Herein below, the method for manufacturing a honeycomb structure according to the embodiment of the present invention will be described in further detail in the order of its process.

Here, a method for manufacturing a honeycomb structure will be described using and example case of producing a honeycomb structure having silicon carbide as the chief component of the constitution material.

It is a matter of course, however, that the chief component of the honeycomb structure is not limited to silicon carbide. Examples of substances suited to use as the chief component of the honeycomb structure include nitride ceramics such as aluminum nitride, silicon nitride, boron nitride and titanium nitride, carbide ceramics such as zirconium carbide, titanium carbide, tantalum carbide and tungsten carbide, and oxide ceramics such as alumina, zirconia, cordierite, mullite and aluminum titanate, and the like.

Also, examples of constitution material include silicon-containing ceramic of the above-mentioned ceramic blended with metallic silicon, ceramic bonded with silicon, a silicate compound, and the like.

In a case of producing the aggregated honeycomb structure, it is desirable that the above-mentioned constitution material is silicon carbide or silicon-containing silicon carbide of silicon carbide blended with metallic silicon, and in a case of producing the integral honeycomb structure, it is desirable that the above-mentioned constitution material is cordierite or aluminum titanate.

In the method for manufacturing a honeycomb structure according to the embodiment of the present invention,

(1-1) first, organic binder is dry mixed with an inorganic powder such as silicon carbide powder having a varying average particle diameter as the ceramic raw material. While the powder blend is being prepared, a solution blend is prepared by blending liquid plasticizer, lubricating agent, and water. Next, the above-mentioned powder blend and the above-mentioned solution blend are further blended together using a wet mixer, and thus a moist mixture for use in manufacturing the molded body is prepared.

Although the particle diameter of the above-mentioned silicon carbide powder is not particularly limited, a particle diameter having little shrinkage during the firing process is preferable. For example, a powder mix of powders of 100 parts by weight having an average particle diameter of at least about 0.3 μm and at most about 50 μm and powders of at least about 5 parts by weight and at most about 65 parts by weight having an average particle diameter of at least about 0.1 μm and at most about 1.0 μm is desirable.

Although in order to adjust the pore diameter and the like of the honeycomb fired body, it is necessary to adjust the firing temperature, the pore diameter can also be adjusted by adjusting the particle diameter of the inorganic powder.

The above-mentioned organic binder is not limited in particular, and for example, binders such as methylcellulose, carboxymethyl cellulose, hydroxyethyl cellulose and polyethylene glycol are acceptable for use therein. Of the binders mentioned above, methylcellulose is the more preferable.

It is desirable that the above-mentioned binder be blended with the inorganic powder at a ratio of at least about 1 part by weight and at most about 10 parts by weight of binder per 100 parts by weight of inorganic powder.

The above-mentioned plasticizer is not limited in particular, and for example, glycerin and the like are acceptable for use as such.

The above-mentioned lubricating agent is not limited in particular, and for example, polyoxyalkylene compounds such as polyoxyethelyne alkyl ether and polyoxypropylene alkyl ether are acceptable for use as such.

Some concrete examples of lubricating agents are polyoxyethelyn monobutyl ether, polyoxypropylene monobutyl ether and the like.

Also, in some cases, it is unnecessary to use plasticizer or lubricating agent in the above-mentioned solution blend.

Also, when preparing the above-mentioned moist mixture, it is acceptable to use a diffusion medium such as water, organic solvents such as benzol, and alcohol such as methanol, and the like, for example. Further, it is also acceptable to add a mold aiding agent to the above-mentioned moist mixture.

The mold aiding agent is not limited in particular, and for example, ethylene glycol, dextrin, fatty acids, fatty acid soap, poly alcohol and the like may be used.

Further, it is acceptable, according to the need, to add a pore-forming agent such as balloon, which is a micro sized hollow sphere having oxidant family ceramic as a component therein, spherical acrylic particles, graphite and the like, to the above-mentioned moist mixture.

The above-mentioned balloon is not particularly limited, as alumina balloons, glass micro balloons, shirasu balloons, fly ash balloons (FA balloons), mullite balloons and the like, for example, are all acceptable for use. Of the above-mentioned, alumina balloon is the more preferable for use.

Also, it is desirable for the temperature of the moist mixture prepared here, which uses silicon carbide, to be about 28° C. or less. This is because if the temperature is about 28° C. or less, organic binder will hardly undergo gelatinization.

It is also desirable for the organic ratio within the above-mentioned moist mixture to be about 10% by weight or less, and it is also desirable for the moisture content weight of the same moist mixture to be at least about 8% by weight and at most about 20% by weight.

(1-2) Next, this moist mixture is extrusion molded using an extrusion molding method or the like to produce a molded body. The attained molded body is then cut to a prescribed length using a cutting machine or the like to produce a pillar shaped honeycomb molded body in which a plurality of cells are placed in parallel with one another in a longitudinal direction with a cell wall therebetween.

(2) Next, a drying treatment is carried out on the above-mentioned honeycomb molded body.

The above-mentioned drying treatment can be carried out using a drying apparatus such as a microwave drying apparatus, a hot air drying apparatus, a dielectric drying apparatus, a reduced pressure drying apparatus, a vacuum drying apparatus, or a freeze drying apparatus.

This drying treatment may be carried out according to necessity.

(3) Next, according to necessity, an opening-sealing treatment is carried out in which a prescribed amount of plug material paste is filled into the end portion of the cells of the honeycomb molded body, thereby sealing the cells.

Although the above-mentioned plug material paste is not limited in particular, it is preferable that the plug material paste layer, manufactured in the subsequent process, has porosity of at least about 30% and at most about 75%. For example, it is possible to use, as the plug material paste, any one of the above-mentioned moist mixtures.

In a case of filling in the plug material paste, it is desirable to dry the filled-in plug material paste.

(4) Next, according to necessity, a degreasing treatment is carried out under prescribed conditions (at least about 200° C. and at most about 500° C., for example) on the honeycomb molded body in which the above-mentioned plug material paste has been filled.

(5) Moreover, a firing treatment is carried out at a prescribed temperature (at least about 1400° C. and at most about 2300° C., for example) on the degreased honeycomb molded body.

According to doing so it is possible to produce a pillar shaped honeycomb fired in which a plurality of cells are placed in parallel with one another in a longitudinal direction with a cell wall therebetween.

(6) Next, a sealing material paste layer is formed by coating the side surfaces of the honeycomb fired body with a sealing material paste which will be a sealing material layer. After this, another honeycomb fired body is stacked onto the above-mentioned honeycomb fired body sequentially. By carrying out the above process repeatedly and after a prescribed number of honeycomb fired bodies are stacked, the sealing material paste layer is dried and then solidified by carrying out a heating treatment thereon, thereby manufacturing an aggregated body of honeycomb fired bodies (a honeycomb aggregated body) of prescribed size, the honeycomb fired bodies combined with one another by interposing the sealing material layer (adhesive layer).

It is possible to use a substance containing inorganic fibers and/or inorganic particles, inorganic binder and organic binder, for example, as the above-mentioned sealing material paste.

It is acceptable to use silica sol, alumina sol and the like as the above-mentioned inorganic binder. Also, each of the above materials may be used alone, or two or more of them may be used in combination. Of the above-mentioned inorganic binders, silica sol is more preferable for use.

It is acceptable to use polyvinyl alcohol, methylcellulose, ethylcellulose, carboxy methylcellulose, and the like, for example, as the above-mentioned organic binder. Also, each of the above materials may be used alone, or two or more of them may be used in combination. Of the above-mentioned organic binders, carboxy methylcellulose is more preferable for use.

It is acceptable to use ceramic fibers such as silica-alumina, mullite, alumina and silica, and the like, for example, as the above-mentioned inorganic fibers. Also, each of the above materials may be used alone, or two or more of them may be used in combination. Of the above-mentioned inorganic fibers, alumina fiber is more preferable for use.

It is acceptable to use carbide, nitride, and the like, for example, as the above-mentioned inorganic particles. More specifically, it is acceptable to use inorganic powder and the like comprised of silicon carbide, silicon nitride, boron nitride, or the like, for example, as the above-mentioned inorganic particles. Each of the above materials may be used alone, or two or more of them may be used in combination. Of the above-mentioned inorganic particles, silicon carbide, which excels in its thermal conductivity properties, is more preferable for use.

And furthermore, it is also acceptable, according to need, to add a pore-forming agent such as balloon which is a micro sized hollow sphere having oxidant family ceramic as a component therein, spherical acrylic particles, or graphite and the like, to the above-mentioned sealing material paste.

The above-mentioned balloon is not particularly limited, as alumina balloons, glass micro balloon, shirasu balloon, fly ash balloon (FA balloon), mullite balloon and the like, for example, are all acceptable for use. Of the above-mentioned, alumina balloon is more preferable for use.

(7) Next, using a diamond cutter or the like, a cutting treatment is carried out on the honeycomb aggregated body in which a plurality of honeycomb fired bodies are adhered with one another by interposing the sealing material layer (the adhesive layer) to produce a cylindrical shaped honeycomb block.

(8) Next, according to need, by forming another sealing material layer on the outer circumference of the honeycomb block using the above-mentioned sealing material paste, it is possible to produce a honeycomb structure having the sealing material layer (the coat layer) disposed thereon the outer circumference portion of a cylindrical honeycomb block comprised of a plurality of honeycomb fired bodies combined with one another by interposing the sealing material layer (the adhesive layer).

(9) Afterward, according to need, it is acceptable to support a catalyst on the honeycomb structure. Also, the above-mentioned supporting of the catalyst may be carried out on the honeycomb fired bodies at the point before the honeycomb fired bodies are manufactured into the honeycomb aggregated body.

In a case where the catalyst is supported, it is preferable that a film of alumina, which has a high specific surface area, be formed onto the surface of the honeycomb structure, and a co-catalyst or a catalyst such as platinum is applied to the surface of the alumina film.

Examples of the above-mentioned method of forming the alumina film onto the surface of the above-mentioned honeycomb structure include a method of impregnating the honeycomb structure with solution of a metallic compound containing an aluminum species such as Al(NO₃)₃ and the like, for example, and then heating, a method of impregnating the honeycomb structure with a solution containing alumina powder and then heating, or like methods.

Examples of the above-mentioned method of applying the co-catalyst onto the above-mentioned alumina film include a method of impregnating the honeycomb structure with solution of a metallic compound containing a rare earth element such as Ce(NO₃)₃ and the like, for example, and then heating, or like methods.

Examples of the above-mentioned method of applying the catalyst onto the above-mentioned alumina film include a method of impregnating the honeycomb structure with a substance such as a dinitrodiamine platinum nitric acid solution ([Pt(NH₃)₂(NO₂)₂]HNO₃, platinum content about 4.53% by weight) and then heating, and other like methods.

Also, it is acceptable to apply the catalyst with a method of first applying the catalyst to alumina particles in advance, and subsequently impregnating the honeycomb structure with the solution containing the alumina powder.

Although the method for manufacturing a honeycomb structure according to the embodiment put forth up to this point is a method for manufacturing an aggregated honeycomb structure, the honeycomb structure to be manufactured according to the method for manufacturing a honeycomb structure according to the embodiment of the present invention may also be an integral honeycomb structure.

In a case of manufacturing an integral honeycomb structure of this sort, the only aspect that is different than in a case of manufacturing an aggregated honeycomb structure is that the size of the extrusion molded honeycomb molded body in the case of manufacturing an integral type honeycomb structure is larger than in the case of manufacturing the aggregate type honeycomb structure, and all other aspects used to manufacture an integral honeycomb structure are identical to those used [the above-mentioned processes (1-1) and (1-2)] in manufacturing an aggregated honeycomb structure.

Next, in the same manner as in the production of the aggregated honeycomb structure, according to necessity, a drying treatment and an opening-sealing treatment [the above-mentioned processes (2) and (3)] are carried out, and afterward, in the same manner as in the production of the aggregated honeycomb structure, a degreasing treatment and a firing treatment [the above-mentioned processes (4) and (5)] are carried out to produce a honeycomb block. Then, according to necessity, by forming a seal material layer (the coat layer) [the above-mentioned process (8)], it is possible to produce an integral honeycomb structure. It is also acceptable to carry out the process [the above-mentioned process (9)] of supporting the catalyst described above on the above-mentioned integral honeycomb structure as well.

In the method for manufacturing a honeycomb structure according to the embodiment of the present invention, during the above-described successive processes, after temporarily storing the treated honeycomb molded body situated atop the conveyer portion in the molded body storage container, the treated honeycomb molded body placed in the above-mentioned molded body storage container is accordingly taken out from the molded body storage container and placed atop a conveyer portion headed to a subsequent process.

Specifically, in the method for manufacturing a honeycomb structure according to the embodiment of the present invention, in a case of carrying out the drying treatment [the above-mentioned process (2)] and the firing treatment [the above-mentioned process (5)], it is preferable the treated honeycomb molded body placed inside of the molded body storage container is the one on which the drying treatment [the above-mentioned process (2)] and/or the firing treatment [the above-mentioned process (5)] is carried out.

This is because these treated honeycomb molded bodies are particularly suited to being held temporarily. This also, is because if a pre-dried honeycomb molded body produced through the above-mentioned process (1) is to be temporarily stored before carrying out the drying treatment thereon, for example, it is impossible for the honeycomb molded body being stored to retain its shape due to the presence of a liquid binder therein, giving a rise to the concern of a possible change in the dimensions of the honeycomb molded body. On the other hand, the concern over a change in the physical properties of the honeycomb molded body having the above-mentioned drying treatment carried out thereon or the honeycomb molded body having the above-mentioned firing treatment carried out thereon is extremely small even stored for a long term.

Also, in the method for manufacturing a honeycomb structure according to the embodiment of the present invention, in cases of producing a honeycomb structure intended to function as a filter (i.e. a honeycomb structure in which a plug material layer is formed on either end portion of the cells), it is preferable that the treated honeycomb molded body placed inside of the molded body storage container be the one on which any of the drying treatment [the above-mentioned process (2)], the opening-sealing treatment [the above-mentioned process (3)] and the firing treatment [the above-mentioned process (5)] is carried out.

This is because the concern over a change in the dimensions of a honeycomb structure on which these treatments have been carried out is extremely small even during a long term storage, being particularly suitable to a temporary storage.

For example, as has been put forth above, if a pre-dried honeycomb molded body produced through the above-mentioned process (1) is to be stored before carrying out the drying treatment thereon, it is difficult for the honeycomb molded body being stored to retain its shape due to the presence of a liquid binder therein, giving a rise to the concern of a possible change in the dimensions of the honeycomb molded body. On the other hand, the concern over a change in the physical properties of the honeycomb molded body having the above-mentioned drying treatment carried out thereon, of the honeycomb molded body having the above-mentioned opening-sealing treatment carried out thereon, or of the honeycomb molded body having the above-mentioned firing treatment carried out thereon is extremely small even stored for a long term.

Also, as a honeycomb structure to be manufactured, even though a honeycomb filter also used for the purpose of capturing airborne particulates within exhaust gas has been the center of description up till this point, the honeycomb structure to be manufactured according to the embodiment of the present invention can be also suitable to be used as a catalyst supporting carrier (a honeycomb catalyst) configured to convert exhaust gas.

The operation of temporarily storing a honeycomb molded body in this kind of method for manufacturing a honeycomb structure according to the embodiment of the present invention can be carried out using the honeycomb molded body receiving apparatus according to the embodiment of the present invention or the honeycomb molded body taking-out apparatus according to the embodiment of the present invention, which will be described next.

In the honeycomb molded body receiving apparatus according to the embodiment of the present invention, it is easier to optimally carry out the operation of placing a treated honeycomb molded body into a molded body storage container, and with the honeycomb molded body taking-out apparatus according to the embodiment of the present invention, it becomes easier to optimally carry out the operation of taking out a treated honeycomb molded body from inside of a molded body storage container.

The description of the honeycomb molded body receiving apparatus according to the embodiment of the present invention will be given referring to the figures. Here, a honeycomb molded body receiving apparatus according to the embodiment of the present invention will be described using an example of a case in which the treated honeycomb molded body is the one on which the drying treatment has been carried out.

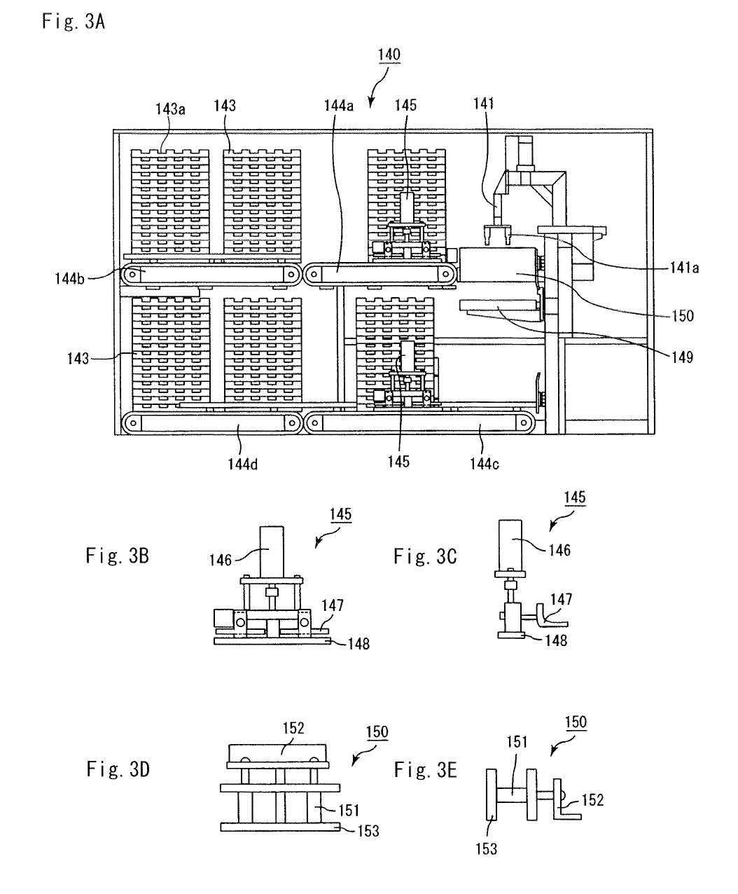

FIG. 3A is a front view schematically showing a honeycomb molded body receiving apparatus according to the embodiment of the present invention. FIG. 3B is a front view showing a storage container lifting apparatus including the honeycomb molded body receiving apparatus according to the embodiment shown in FIG. 3A. FIG. 3C is a side view of the storage container lifting apparatus according to the embodiment shown in FIG. 3B. FIG. 3D is a plan view of a storage container support apparatus including the honeycomb molded body receiving apparatus according to the embodiment shown in FIG. 3A. FIG. 3E is a side view of the storage container support apparatus according to the embodiment shown in FIG. 3D.

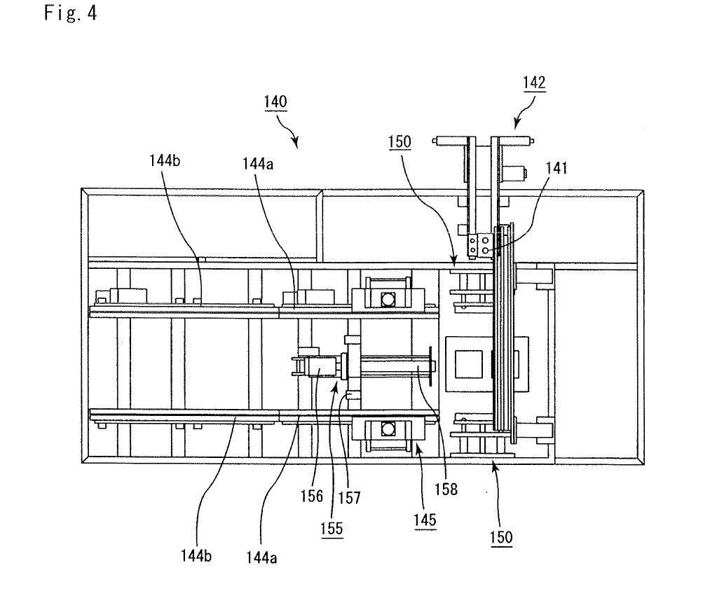

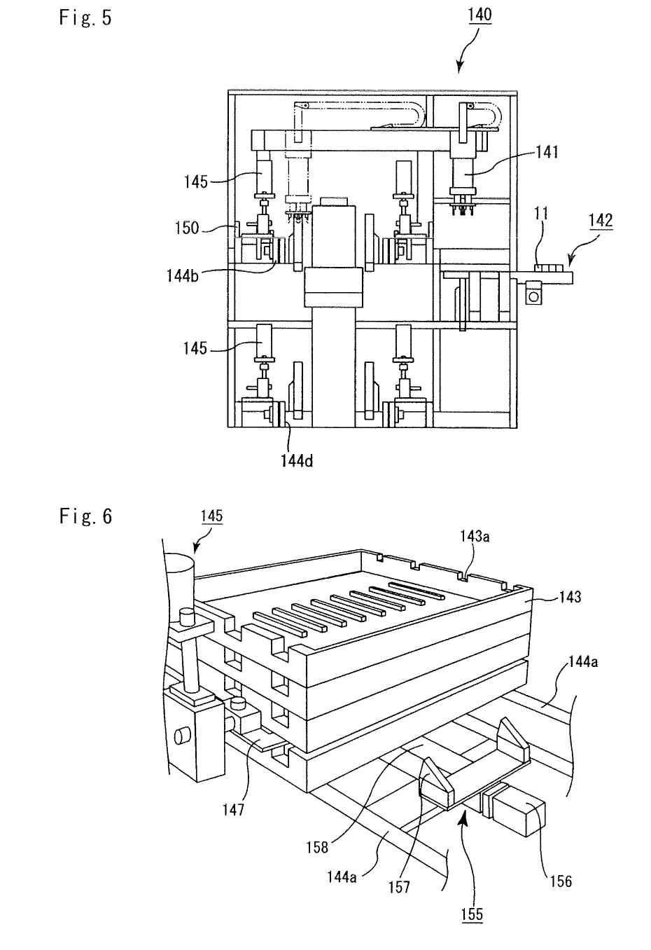

Also, FIG. 4 is a plan view of the honeycomb molded body receiving apparatus according to the embodiment shown in FIG. 3A. FIG. 5 is a side view of the honeycomb molded body receiving apparatus according to the embodiment shown in FIG. 3A. FIG. 6 is an enlarged perspective view showing a close up of the storage container lifting apparatus and a storage container moving apparatus including the honeycomb molded body receiving apparatus according to the embodiment shown in FIG. 4.

As shown in FIG. 3A and FIGS. 4 to 6, this honeycomb molded body receiving apparatus 140 mainly includes a robotic arm 141 which lifts a honeycomb molded body (treated honeycomb molded body) 11 on which a drying treatment is carried out and moves it; belt conveyers 144a, 144b, 144c, 144d which stack molded body storage containers 143 and store these inside the honeycomb molded body receiving apparatus 140, and also moves the molded body storage containers 143; a storage container lifting apparatus 145 which lifts up molded body storage containers 143 other than a single molded body storage container 143 when withdrawing the single molded body storage container 143 from the stacked molded body storage containers 143, or when stacking yet another molded body storage container 143 onto the stacked molded body storage containers 143; a storage container support apparatus 150 which supports the molded body storage container 143 when successively storing the treated honeycomb molded bodies 11 inside of the molded body storage container 143; a storage container moving apparatus 155 (see FIG. 4) which functions when moving only the bottom-most molded body storage container 143 in the stacked molded body storage containers 143; and a storage container elevator apparatus 149 which is able to ascend and descend with having a single or a plurality of the molded body storage containers 143 placed thereon.

As shown in FIGS. 4 and 5, a belt conveyer 142 configured to have the treated honeycomb molded body 11 placed thereon and move the treated honeycomb molded body 11 to the honeycomb molded body receiving apparatus 140 is disposed in close proximity of the honeycomb molded body receiving apparatus 140. Also, the molded body storage container 143 has a rectangular shape when viewed from the top, and as shown in FIGS. 3A and 6, it is provided with four gaps 143a on the portion of its side faces corresponding to its short sides in order to allow insertion of a member configured to lift up another molded body storage container 143 stacked on the top of the molded body storage container 143. The molded body storage container 143 may have a square shape or other kinds of shapes when viewed from the top, and any number of gaps may be provided thereon.

Here, first description will be given in regard to a case in which the molded body storage containers 143 stacked atop the belt conveyers 144a, 144b of the upper tier of the honeycomb molded body receiving apparatus 140 are empty and are not currently storing any treated honeycomb molded body 11, and the molded body storage containers 143 stacked atop the belt conveyers 144c, 144d of the lower tier of the honeycomb molded body receiving apparatus 140 are in a state of currently storing a regulated number of treated honeycomb molded bodies 11 within.

In this case, from the empty molded body storage containers 143 conveyed in from the outside and held in a state stacked atop the belt conveyers 144a, 144b, a single molded body storage container 143 is moved to a location at which there is disposed a storage container support apparatus 150, and at this location the treated honeycomb molded body 11 is stored into the interior of the molded body storage container 143. Afterward, the molded body storage container 143 is stacked atop the storage container elevator apparatus 149, after which the stacked body of molded body storage containers 143 is moved to and held on the belt conveyers 144c, 144d of the lower tier, and is then moved to a suitable storage area and stored.

Therefore, in a honeycomb molded body receiving apparatus 140 in which the molded body storage container is set into motion in this sort of direction, the belt conveyer 144b of the upper tier functions as a molded body pre-storage container induction portion, while the belt conveyer 144d functions as a molded body post-storage container taking-out portion.

The procedure by which the treated honeycomb molded body is placed within the molded body storage container 143 in this case will be explained in greater detail.

The empty molded body storage container 143 conveyed in from the outside and held on the belt conveyer 144b of the upper tier, which functions as the molded body pre-storage container induction portion, is conveyed by the belt conveyers 144a, 144b to the location occupied by the storage container lifting apparatus 145.

As shown in FIG. 3B, FIG. 3C, and FIG. 6, this storage container lifting apparatus 145 includes a lifting portion 147 configured to directly lift up the molded body storage container 143, an air cylinder 146 for the purpose of moving the lifting portion 147 in the upward and downward directions, and a platform portion 148 configured to support the air cylinder 146, and is disposed on both sides sandwiching the path of the molded body storage container 143. Also, although not shown in the figures there is an air cylinder also disposed in the lifting portion 147, and it is configured in a manner enabling the lifting portion 147 to be moved in the horizontal direction.

When lifting up the molded body storage container 143, the lifting portion 147 of the storage container lifting apparatus 145 situated on both sides of the molded body storage container 143 is first moved in the horizontal direction, then the end of the lifting portion 147 is inserted into the gaps at the bottom-most portion of the stacked molded body storage containers 143, and the air cylinder 146 is driven to lift the lifting portion 147. According to this, all the molded body storage containers 143 of the second tier and above are lifted upwards thereby separating the bottom-most molded body storage container 143 from the molded body storage containers 143 of the second tier and above.

Next, the molded body storage container 143 is moved using the storage container moving apparatus 155. The storage container moving apparatus 155, as shown in FIG. 4 and FIG. 6, protrudes in the upward direction, and includes a catch portion 157 configured to catch the molded body storage container 143 when moving in the direction of the molded body storage container 143, and a motor 156 and ball screw 158 configured to move the catch portion 157. The catch portion 157 screwed onto the ball screw 158 is configured in a manner able to move in the direction of the molded body storage container 143 or the reverse direction by driving the motor 156 and rotating the ball screw 158.

Therefore, the molded body storage container 143 is moved by first driving the motor 156, which thereby rotates the ball screw 158 to set the catch portion 157 into motion in the direction of the molded body storage container 143, and when the catch portion 157 reaches the molded body storage container 143, it catches the molded body storage container 143 and moves the molded body storage container 143 to the location between the two storage container support apparatuses 150 shown in FIG. 3A. At this time, the belt conveyer 144a is also to be set into rotation to assist the movement of the molded body storage container 143.

Therefore, in a case of running the honeycomb molded body receiving apparatus 140 using this procedure, the storage container moving apparatus 155 functions as a first molded body storage container moving mechanism configured to move the above-mentioned empty molded body storage container in the horizontal direction and situate the above-mentioned molded body storage container at a prescribed location.

As shown in FIG. 3D and FIG. 3E, the storage container support apparatus 150 includes a storage container support portion 152 which is for the purpose of supporting a molded body storage container 143 moved toward it; an air cylinder 151 which is for the purpose of moving the storage container support portion 152 in the direction nearing the molded body storage container 143 when supporting the molded body storage container 143, and alternately moving the storage container support portion 152 in the direction away from the molded body storage container 143 when releasing a supported molded body storage container 143; and a cylinder support portion 153 configured to support the air cylinder 151. As shown in FIG. 4, there are two units of the storage container support apparatuses 150 disposed on both sides of the region through which the molded body storage container 143 moves.

Also, the two storage container support apparatuses 150 maintain in advance two storage container support portions 152 at a prescribed space interval, which makes it possible to support a molded body storage container 143 when the molded body storage container 143 is moved to the storage container support apparatuses 150. Therefore, when a molded body storage container 143 is moved by the movement of the catch portion 157 to the location of the storage container support apparatuses 150, the storage container support apparatuses 150 support the molded body storage container 143 from both sides while driving the air cylinder 151 to further advance the storage container support portion 152 in the direction of the molded body storage container 143 to thereby hold the molded body storage container 143 firmly.

Next, according to the robotic aim 141, a treated honeycomb molded body 11 is placed within the interior of the molded body storage container 143 and stored.

This robotic arm 141 includes a gripper portion 141a comprised of a suction portion configured to carry out air suction (not shown) and a plate-shaped member used for holding in a sandwiching manner. Using the suction portion and the gripper portion 141a, the robotic arm 141 lifts up a treated honeycomb molded body 11 placed on a belt conveyer 142 and conveyed to it, and moves the robotic arm 141 to a molded body storage container 143 situated inside of the honeycomb molded body receiving apparatus 140. After that, the suction of the suction portion is halted and the gripper portion 141a is spread apart, and the treated honeycomb molded bodies 11 are placed inside the molded body storage container 143 sequentially.

Then, after placing the treated honeycomb molded bodies 11 in the entire interior of the molded body storage container 143 and the storage process of treated honeycomb bodies 11 has been completed, the storage container elevator apparatus 149 situated in between the two storage container support apparatuses 150 ascends and supports the molded body storage container 143. After this, the storage container support apparatuses 150 drive the air cylinder 151 to retract the storage container support portion 152 from the molded body storage container 143 thereby releasing the molded body storage container 143 from support. According to doing so, the molded body storage container 143 is set into a state in which it is supported only by the storage container elevator apparatus 149. After this, the storage container elevator apparatus 149 descends, which allows movement of a new molded body storage container 143 to the location between the two storage container support apparatuses 150.

Therefore, the storage container elevator apparatus 149 comes to function as a second molded body storage container.

According to repeating the above-mentioned process, molded body storage containers 143 having their interiors filled with a prescribed number of the treated honeycomb molded bodies 11 come to be stacked there atop the storage container elevator apparatus 149. When the number of the molded body storage containers 143 stacked on the storage container elevator apparatus 149 reaches a prescribed value (for example, 15 layers), the storage container elevator apparatus 149 descends to the bottom-most point of its movable range, and places the stacked molded body storage containers 143 there on the belt conveyer 144c. Next, according to driving the belt conveyer 144a, the stacked molded body storage containers 143 are set into motion, thereby securing a place to set down the next stacked body of molded body storage containers 143.

After this, the stacked molded body storage containers 143 are held on the belt conveyer 144c and the belt conveyer 144d, and are further set into motion according to the movement of the belt conveyers 144c, 144d successively toward the exit side. After this, the stacked molded body storage containers 143 are further moved to a suitable storage site outside of the honeycomb molded body receiving apparatus 140 where they are stored.

Also, in the honeycomb molded body receiving apparatus according to the embodiment of the present invention, when placing the treated honeycomb molded body as in the manner of the honeycomb molded body receiving apparatus 140 running by the above-described procedure, it is preferable that the location where the empty molded body storage container 143 is to be situated is at the upper side with respect to the location where the molded body storage container 143 having the treated honeycomb molded body placed therein is to be stacked.

This is because by configuring in such a manner, it becomes easier to design the honeycomb molded body receiving apparatus to be compact. Also, in a case in which the stacked molded body storage containers are situated at the lower side with respect to the empty molded body storage containers, since the distance over which the molded body storage container having the treated honeycomb molded body placed therein is to be moved is either small, or the molded body storage container need not be moved at all, the operation of conveying the molded body storage container is easy.

In the honeycomb molded body receiving apparatus 140 shown in FIG. 3A and FIGS. 4 to 6, since the storage container lifting apparatus 145 is also established at the lower tier, it is acceptable to carry out the process of stacking the molded body storage container 143 or the like at the lower tier as well.

Description will be put forth herein below regarding the operation procedure of the honeycomb molded body receiving apparatus 140 in such a case.

In a case in which the process of stacking the molded body storage container 143 is carried out at the lower tier, the treated honeycomb molded body is placed inside of the molded body storage container 143 supported by the storage container support apparatuses 150 in the same manner as the operation already described above, and this molded body storage container 143 is further supported by the storage container elevator apparatus 149.

Then, with the storage container elevator apparatus 149 in a state of supporting a single molded body storage container 143, the storage container elevator apparatus 149 is made to descend to the lowest point of its movable range, and place the molded body storage container 143 on the belt conveyer 144c. Afterward, the molded body storage container 143 is moved according to the belt conveyer 144c to a location in between the two storage container lifting apparatuses 145 of the lower tier.

Next, according to carrying out a process of the same fashion, the next molded body storage container 143 is placed onto the belt conveyer 144c and moved according to the movement of the belt conveyer 144c to a spot in between the two storage container lifting apparatuses 145.

At this time, the first conveyed molded body storage container 143 is lifted up by the storage container lifting apparatus 145 to a height enabling the next molded body storage container 143 to be moved in underneath.

Then, after having conveyed the second molded body storage container 143 by the belt conveyer 144c to a prescribed location, the first molded body storage container 143 is stacked there on top.

According to carrying out this kind of process repeatedly, it is possible to carry out the process of stacking the molded body storage container 143 on the lower tier.

Also, in this case as well, when a prescribed number of the molded body storage container 143 is stacked, the stacked body is sent out to the belt conveyer 144d side.

In a case of carrying out the process of stacking the molded body storage container with this kind of procedure, the storage container lifting apparatus 145 and the belt conveyer 144c of the lower tier come to function as second molded body storage container mechanisms.

According to using a honeycomb molded body receiving apparatus configured in this formation under the above-described procedure, it becomes easier to carry out the operation of placing the treated honeycomb molded body into the molded body storage container in an optimal manner.

Also, in the already described procedure, molded body storage containers are stacked on both the upper tier belt conveyer as well as the lower belt conveyer, the empty molded body storage containers being stacked on the upper tier belt conveyer while the molded body storage containers having the treated honeycomb molded bodies placed therein being stacked on the lower tier belt conveyer. However, the operation procedure of the honeycomb molded body receiving apparatus 140 according to the embodiment of the present invention is not limited to a procedure in this formation, as it is also acceptable to realize the same according to a procedure such as that described below.

For example, it is also acceptable for the direction of movement of the molded body storage container 143 to be in the opposite direction.

To be more specific, first, with the belt conveyer 144d of the lower tier serving as the molded body pre-storage container induction portion, the empty molded body storage container 143 stacked on the belt conveyers 144d, 144c of the lower tier are held in place, all molded body storage containers 143 except the bottom-most molded body storage container 143 are lifted up according to the storage container lifting apparatus 145 of the lower tier, and the bottom-most molded body storage container 143 is made to be supported by the storage container elevator apparatus 149 according to the movement of the belt conveyer 144c.

Next, the storage container elevator apparatus 149 is made to ascend, and the molded body storage container 143 is further supported by the storage container support apparatus 150, and the treated honeycomb molded body is placed inside of the molded body storage container 143 by the robotic arm 141.

Afterward, the molded body storage container 143 having the treated honeycomb molded body placed therein is placed on the belt conveyer 144a.

Then according to carrying out this process repeatedly, the molded body storage container 143 having the treated honeycomb molded body placed therein is placed on the belt conveyer 144a.

When stacking the molded body storage container 143 on the belt conveyer 144a, it is acceptable to conduct the stacking of the molded body storage container 143 on the belt conveyer 144a according to lifting up a previously conveyed-in molded body storage container 143 according to the storage container lifting apparatus 145 of the upper tier and successively sending in subsequent molded body storage container 143 underneath.

Moreover, when the number of stacked molded body storage containers 143 reaches a prescribed number, the stacked body of molded body storage containers 143 is further conveyed to the belt conveyer 144b. Therefore, in a case of placing the treated honeycomb molded body inside of the molded body storage container 143 under this sort of procedure, the belt conveyer 144b comes to function as a molded body post-storage container taking-out portion.

Also, under this sort of procedure, the belt conveyer 144c and the storage container elevator apparatus 149 come to function as first molded body storage container movement mechanisms while the belt conveyer 144a comes to function as a second molded body storage container movement mechanism.

In this manner, the honeycomb molded body receiving apparatus 140 shown in FIG. 3A and FIGS. 4 to 6 may be used in a manner in which the empty molded body storage containers are stacked there on the conveyer belt of the lower tier while the molded body storage containers storing the molded bodies are stacked there on the conveyer belt of the upper tier.

Also, for example, in the honeycomb molded body receiving apparatus 140 shown in FIG. 3A and FIGS. 4 to 6, when moving a stack of empty molded body storage containers 143 held on the belt conveyer 144a to the storage container support apparatus 150, although the bottom-most situated molded body storage container 143 among a stack of empty molded body storage containers 143 on the belt conveyer 144a is successively moved to the storage container support apparatus 150, it is also acceptable for the honeycomb molded body receiving apparatus according to the embodiment of the present invention to be configured in a manner in which when moving a stack of empty molded body storage containers 143 on the belt conveyer 144a to the storage container support apparatus 150, the top-most situated molded body storage container 143 among a stack of empty molded body storage containers 143 on the belt conveyer 144a is successively moved to the storage container support apparatus 150.

In such a case, for example, it is acceptable to include a robotic arm configured to move the top-most situated molded body storage container 143 among a stack of empty molded body storage containers 143 on the belt conveyer 144a to the storage container support apparatus 150.

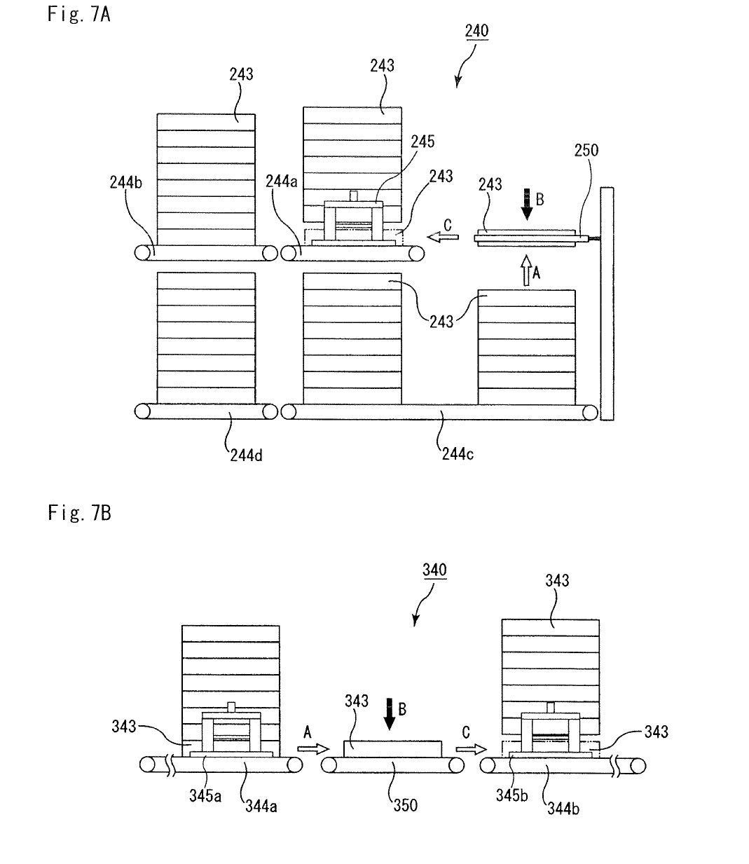

Also, aside from that, it is acceptable for the honeycomb molded body receiving apparatus according to the embodiment of the present invention to have a configuration as shown in FIGS. 7A and 7B.

FIGS. 7A and 7B are descriptive figures for the purpose of describing the other configuration of the honeycomb molded body receiving apparatus according to the embodiment of the present invention.

In a honeycomb molded body receiving apparatus 240, stacked empty molded body storage containers are held on a belt conveyer 244d and a belt conveyer 244c of the lower tier, while molded body storage containers having the treated honeycomb molded bodies placed therein are held on a belt conveyer 244a and a belt conveyer 244b of the upper tier.

In the honeycomb molded body receiving apparatus 240, first, an empty molded body storage container conveyed in from the outside is held in a stacked state on the belt conveyers 244d, 244c of the lower tier.

And in this honeycomb molded body receiving apparatus 240, the belt conveyer 244d comes to function as a molded body pre-storage container induction portion.

Then, when receiving a treated honeycomb molded body, the top-most situated molded body storage container of among a stack of empty molded body storage containers stacked on the belt conveyer 244c of the lower tier is lifted up to a prescribed location according to the storage container support apparatus 250 (see the white arrow A in FIG. 7A).

Then, in the honeycomb molded body receiving apparatus 240, the storage container support apparatus 250 moves an empty molded body storage container 243 in the upward and downward direction to function as a first molded body storage container movement mechanism configured to situate the molded body storage container 243 at a prescribed location.

Next, according to a robotic arm not shown in the figures, a treated honeycomb molded body placed on a conveyer member not shown in figures is placed inside of a molded body storage container supported by the storage container support apparatus 250 (see the black arrow B in FIG. 7A).

Next, the molded body storage container storing inside of it the treated honeycomb molded body is moved on the belt conveyer 244a and the molded body storage container storing inside of it the treated honeycomb molded body on the belt conveyer 244a is then stacked (see the white arrow C in FIG. 7A).

At this time, at the belt conveyer 244a side, in order that the molded body storage container storing inside of it the treated honeycomb molded body may be placed at the bottom-most layer, an already stacked molded body storage container is lifted up and out of the way according to a storage container lifting apparatus 245.

Therefore, in the honeycomb molded body receiving apparatus 240, the belt conveyer 244a and the storage container lifting apparatus 245 come to function as second molded body storage container movement mechanisms.

In this manner, atop the belt conveyer 244a, the molded body storage containers storing inside of them the treated honeycomb molded bodies are successively stacked, and when the number of the stacked molded body storage containers reaches a prescribed value, the stacked molded body storage containers are moved on the belt conveyer 244b of the upper tier, and further conveyed out to the outside.

Therefore, in the honeycomb molded body receiving apparatus 240, the belt conveyer 244b functions as a molded body post-storage container taking-out portion.

And in FIG. 7A, the white arrows indicate the movement of the molded body storage container, while the black arrows indicate the movement of the treated honeycomb molded body.

When placing the treated honeycomb molded body as in the manner of the honeycomb molded body receiving apparatus 240 shown in FIG. 7A, it is preferable for the location of placement of the molded body storage container 243 in the honeycomb molded body receiving apparatus according to the embodiment of the present invention to be at the upper side with respect to the location at which the empty molded body storage containers 243 are to be stacked.

This is because by configuring in such a manner, it becomes easier to design the honeycomb molded body receiving apparatus to be compact. Also, in a case in which the stacked molded body storage containers are situated at the lower side with respect to the empty molded body storage containers, since the distance over which the molded body storage container having the treated honeycomb molded body placed therein is to be moved is either small, or the molded body storage container need not be moved at all, the operation of conveying the molded body storage container becomes easy.

Also, in a honeycomb molded body receiving apparatus 340 shown in FIG. 7B, a belt conveyer 344a holding a stack of empty molded body storage containers and a belt conveyer 344b holding a stack of molded body storage container storing the treated honeycomb molded body are not disposed respectively on upper and lower tiers as in the honeycomb molded body receiving apparatus shown in FIG. 3A, FIG. 4, FIG. 5, FIG. 6 and FIG. 7A, but the belt conveyers 344a, 344b are formed on the same plane with each other.

In the honeycomb molded body receiving apparatus 340, first, empty molded body storage containers conveyed in from the outside are held in a stacked state on the belt conveyer 344a.

Then, when receiving the treated honeycomb molded body, all molded body storage containers of among the empty molded body storage containers 343 stacked on the belt conveyer 344a except the bottom-most molded body storage container 343 are lifted up according to the storage container lifting apparatus 345a, and the bottom-most molded body storage container 343 is then situated on (see the white arrow A in FIG. 7B) a belt conveyer 350.

In the honeycomb molded body receiving apparatus 340, the belt conveyer 350, in the same formation as the storage container support apparatuses 150, 250 of the honeycomb molded body receiving apparatuses 140, 240, respectively, has a function of supporting the molded body storage container when holding the treated honeycomb molded body inside of the molded body storage container.

Next, the treated honeycomb molded body placed on a conveyer member not shown in the figures is placed according to a robotic arm not shown in the figures within the molded body storage container that has been situated on the belt conveyer 350 (see the black arrow B in FIG. 7B).

Next, the molded body storage container in which the treated honeycomb molded body has been stored is then moved on the belt conveyer 344b and is stacked with the molded body storage containers 343 storing treated honeycomb molded bodies on the belt conveyer 344b (see the white arrow C in FIG. 7B).

At this time, on the belt conveyer 344b side, the stack of molded body storage containers already storing treated honeycomb molded bodies is lifted up according to a storage container lifting apparatus 345b in order that the incoming molded body storage container storing the treated honeycomb molded body may be stacked at the bottom-most location.

In this manner, on the belt conveyer 344b, the molded body storage containers storing inside of them the treated honeycomb molded bodies are successively stacked, and when the number of the stacked molded body storage containers reaches a prescribed value, the stacked molded body storage containers are conveyed out to the outside.

In FIG. 7B, the white arrows indicate the movement of the molded body storage container, while the black arrows indicate the movement of the treated honeycomb molded body.

It should be noted that, in the honeycomb molded body receiving apparatus 340 shown in FIG. 7B, the belt conveyer 344a functions as a molded body pre-storage container induction portion while the belt conveyer 344b functions as a molded body post-storage container taking-out portion.

Also, in the honeycomb molded body receiving apparatus 340, the belt conveyer 344a and the belt conveyer 350 both function as first molded body storage container movement mechanisms, while the belt conveyer 344b and the storage container lifting apparatus 345b function as second molded body storage container movement mechanisms.

It is acceptable for the honeycomb molded body receiving apparatus according to the embodiment of the present invention to have a configuration such as shown in FIG. 7A and FIG. 7B.

In this kind of molded body receiving apparatus according to the embodiment, since the process of placing the treated honeycomb molded body into the molded body storage container is configured to be carried out automatically, it becomes easier to carry out placement of the treated honeycomb molded body into the molded body storage container efficiently and without manual effort (manual working).

Next, description will be given in regard to the honeycomb molded body taking-out apparatus according to the embodiment of the present invention.

Although the honeycomb molded body taking-out apparatus according to the embodiment of the present invention is an apparatus configured to take out a treated honeycomb molded body from within a molded body storage container, this honeycomb molded body taking-out apparatus according to the embodiment is an apparatus configured to cany out the complete opposite operation of the honeycomb molded body receiving apparatus according to the embodiment of the present invention already put forth herein above. Aside from the point of the direction of movement of the treated honeycomb molded body in the honeycomb molded body taking-out apparatus being the complete opposite of that in the honeycomb molded body receiving apparatus, since the conveyance direction and the like of the molded body storage container is identical to that in the above-mentioned honeycomb molded body receiving apparatus according to the embodiment, it is possible to use the same apparatus to implement operation.

More specifically, the honeycomb molded body taking-out apparatus according to the embodiment of the present invention includes a robotic arm having a suction mechanism and a gripping mechanism, and third and fourth molded body storage container movement mechanisms. However, here, the robotic arm has a configuration identical to the robotic arm in the honeycomb molded body receiving apparatus according to the embodiment of the present invention, and the third and fourth molded body storage container movement mechanisms of the honeycomb molded body taking-out apparatus each has a configuration identical to the first and second molded body storage container movement mechanisms of the honeycomb molded body receiving apparatus according to the embodiment of the present invention, respectively.

So, in the honeycomb molded body taking-out apparatus according to the embodiment of the present invention, the molded body pre-storage container induction portion in the honeycomb molded body receiving apparatus according to the embodiment of the present invention functions as a molded body post-storage container induction portion, while the molded body post-storage container taking-out portion in the honeycomb molded body receiving apparatus according to the embodiment of the present invention functions as a molded body pre-storage container taking-out portion.

Here, using a case of using an apparatus identical to the honeycomb molded body receiving apparatus 140 shown in FIG. 3A and FIGS. 4 to 6 as the honeycomb molded body taking-out apparatus according to the embodiment as an example, description will be given in regard to the procedure used to take out a treated honeycomb molded body using the honeycomb molded body taking-out apparatus according to the embodiment.

The symbols used in the FIG. 3A and FIGS. 4 to 6 will also be used here in this example.

Also, here, description is carried out using a case of stacking and holding molded body storage containers having treated honeycomb molded bodies placed therein on a belt conveyer of an upper tier, and stacking and holding empty molded body storage containers having the treated honeycomb molded bodies taken out therefrom on a belt conveyer of a lower tier.

In a case of using the honeycomb molded body receiving apparatus 140 as the honeycomb molded body taking-out apparatus, the molded body storage container having the treated honeycomb molded body placed therein is conveyed in a stacked state on the belt conveyer 144b of the upper tier, and is further conveyed to the location of the storage container lifting apparatus 145 on the belt conveyer 144a of the upper tier.

Then, all molded body storage containers 143 except for the bottom-most molded body storage container 143 are lifted up, and the bottom-most molded body storage container 143 is then moved according to the storage container moving apparatus 155 and supported by the storage container support apparatus 150.

Next, the treated honeycomb molded body 11 inside of the molded body storage container 143 supported by the storage container support apparatus 150 is taken out by the robotic aim 141, and the taken-out treated honeycomb molded body 11 is then moved on the belt conveyer 142. The treated honeycomb molded body 11 is now ready to be conveyed to an apparatus of a subsequent process according to the belt conveyer 142.

On the other hand, the molded body storage containers 143 made empty by having the treated honeycomb molded body taken-out therefrom are stacked in succession atop the storage container elevator apparatus 149. When the number of stacked empty molded body storage containers 143 reaches a prescribed value, the stack of molded body storage containers 143 is moved on the belt conveyer 144c and further conveyed on the belt conveyer 144d where after it is conveyed out to the outside of the apparatus.

In a case using an apparatus identical to the honeycomb molded body receiving apparatus 140 shown in FIG. 3A and FIGS. 4 to 6 as the honeycomb molded body taking-out apparatus, it is possible to take out the treated honeycomb molded body from the molded body storage container using the above-mentioned procedure for example.

In a case using an apparatus identical to the honeycomb molded body receiving apparatus 140 as the honeycomb molded body taking-out apparatus, it is of course acceptable to carry out the stacking of the molded body storage container on the belt conveyer 144c of the lower tier, and also, it is acceptable after situating the molded body storage containers having the treated honeycomb molded bodies placed therein on the belt conveyers 144c, 144d of the lower tier and taking out the treated honeycomb molded bodies with the robotic arm, to hold the empty molded body storage containers there on the belt conveyer 142 of the upper tier.

It is also acceptable for the honeycomb molded body taking-out apparatus according to the embodiment of the present invention to be an apparatus configured identical to a honeycomb molded body receiving apparatus according to the embodiment of the present invention other than the honeycomb molded body receiving apparatus 140, such as the honeycomb molded body receiving apparatus 240, or the honeycomb molded body receiving apparatus 340 shown in FIGS. 7A and 7B.

It is desirable that in the honeycomb molded body receiving apparatus according to the embodiment of the present invention, the location at which the above-mentioned molded body storage container is situated is at the upper side with respect to the location at which the above-mentioned empty molded body storage container is to be stacked when lifting the above-mentioned treated honeycomb molded body by using the holding portion.

This is because by configuring in this manner, it becomes easier to design the honeycomb molded body taking-out apparatus to be compact. Also, in a case in which the stacked molded body storage containers are situated at the lower side with respect to the molded body storage containers, since the distance over which the molded body storage container having the treated honeycomb molded body placed therein is to be moved is either small, or the molded body storage container need not be moved at all, the operation of conveying the molded body storage container becomes easy.

Also, it is desirable that in the honeycomb molded body receiving apparatus according to the embodiment of the present invention, the location at which the above-mentioned molded body storage container is situated is at the upper side with respect to the location at which the above-mentioned stacked molded body storage containers having the treated honeycomb molded bodies placed therein are to be held when lifting the above-mentioned treated honeycomb molded body by using the holding portion.

This, also, is because by configuring in this manner, it becomes easier to design the honeycomb molded body taking-out apparatus to be compact. Also, in a case in which the stacked molded body storage containers are situated at the lower side with respect to the molded body storage containers, since the distance over which the molded body storage container having the treated honeycomb molded body placed therein is to be moved is either small, or the molded body storage container need not be moved at all, the operation of conveying the molded body storage container becomes easy.

With this kind of honeycomb molded body taking-out apparatus according to the embodiment, since the process of taking out the treated honeycomb molded body from the molded body storage container is carried out automatically, it becomes easier to carry out removal of the treated honeycomb molded body from the molded body storage container efficiently and without manual effort (manual working).

In addition, conveyers of a honeycomb molded body receiving apparatus and a honeycomb molded body taking-out apparatus are not limited to belt-conveyers, and may be chain conveyers, roller conveyers, pallet conveyers, and the like.

In a method for manufacturing a honeycomb structure, in order to improve productivity performance it is desirable to carry out the production of the honeycomb structure according to a single continuous production line in which each of the processes therein runs continuously.

However, in a case in which the entire process runs continuously with synchronization with one another, when a trouble has arisen in one of the processes and the operation of the process must be halted, it becomes necessary to halt the operation of other processes in which no trouble has arisen; this could result in a remarkable decrease in productivity.

Also, depending upon the process, there are processes that, after the completion of a certain process, the next process is required to run continuously (within a prescribed period of time). And in a case in which a trouble has arisen in a process after these processes, thereby requiring the halting of the entire production line, even if all the processing up to a certain process has been completed, it is impossible to carry on to the next process within a prescribed period of time. Thus, it could result in a case where the immature product of the processes that have been completed up to the certain process must be discarded.

More specifically, for instance, after having produced a honeycomb molded body by carrying out extrusion molding and then cutting the molded body into a prescribed length, if a trouble arises in or after a drying process in a production line in which the molded body must be conveyed to the drying process within a prescribed period of time and it becomes necessary to halt the entire production line including the drying process, even if the production of the honeycomb molded body has been assuredly completed, the molded body is not able to be conveyed to the drying process. Thus, it could result in a case where the produced honeycomb molded body must ultimately be discarded.

The method for manufacturing a honeycomb structure according to the embodiment of the present invention is free from the restriction of needing the entire honeycomb molded body production line halted if a trouble arises in any of the processes in the production line, and is able to prevent a decrease in productivity.

### EXAMPLES

% The description of the present invention will be given in further detail with examples below. However, the present invention is not limited to only these examples.

### Example 1

(1) 250 kg of α-type silicon carbide powder having an average particle diameter of 10 μm, 100 kg of α-type silicon carbide powder having an average particle diameter of 0.5 μm, and 20 kg of organic binder (methylcellulose) were blended together to prepare a powder mixture.

Next, 12 kg of lubricating agent (UNILUB, Manufactured by NOF Corp.), 5 kg of plasticizer (glycerin), and 65 kg of water were blended in a separate container to prepare a liquid mixture. Next, using a wet mixer, the powder mixture and the liquid mixture were blended together, thereby preparing the moist mixture.

Next, using a conveyer, the moist mixture was conveyed to the extrusion molding machine and inducted into a raw material induction port of the extrusion molding machine.

Then, a honeycomb molded body having a shape identical to that shown in FIG. 2A, except that the end portion of the cells are not yet plugged, is produced according to carrying out cutting of the extruded molded body.

(2) Next, the above-mentioned honeycomb molded body was dried using a drying apparatus combining microwaves and hot air.

Afterward, the honeycomb molded body on which the drying treatment has been carried out was placed into a molded body storage container using the honeycomb molded body receiving apparatus 140 shown in FIG. 3A and FIGS. 4 to 6, and stored for approximately one week.

Afterward, using a honeycomb molded body taking-out apparatus having the same configuration as the honeycomb molded body receiving apparatus 140, the dried honeycomb molded body that underwent storage was taken out and conveyed to a subsequent process.

(3) Next, a plug material paste having the same composition as the above-mentioned moist composite was filled into prescribed cells of the honeycomb molded body in a fashion in which the plug material paste is filled into either end portion of the cells.

Next, the filled plug material paste was dried according to irradiating both end faces of the honeycomb molded body with hot air at a temperature of 130° C.

(4) Next, the honeycomb molded body which has had the plug material paste filled into its cells was carried into a degreasing furnace where degreasing treatment was carried out on it.

Here, the degreasing conditions were set to 400° C. for a 3-hour time period.

(5) Next, the degreased honeycomb molded body is carried into a firing furnace, where firing treatment was carried out.

Here the firing conditions were a 2200° C. argon atmosphere at atmospheric pressure for a 3-hour time period.

According to this kind of firing treatment, a honeycomb fired body made from a silicon carbide fired body having a porosity of 40%, an average pore diameter of 12.5 μm, a size of 34.3 mm×34.3 mm×254 mm, with the number of cells (cell density) of 46.5 pcs/cm², and a cell wall thickness of 0.25 mm was produced.

(6) Next, using a thermal resistant sealing material paste having 30% by weight of alumina fiber having an average fiber length of 20 μm, 21% by weight of silicon carbide granule with an average particle diameter of 0.6 μm, 15% by weight of silica sol, 5.6% by weight of carboxy methylcellulose, and 28.4% by weight of water, a multitude of the honeycomb fired bodies was adhered to one another and further dried at a temperature of 120° C. to produce a honeycomb aggregated body.

Here, the thickness of the sealing material layer (the adhesive layer) was set to 1.0 mm.

(7) Next, a cylindrical shaped honeycomb block was produced according to cutting the outer circumference of the honeycomb aggregated body using a diamond cutter.

(8) Next, a sealing material paste was prepared by mixing and kneading together a mixture of 23.3% by weight of silica aluminum fiber (average fiber length 100 μm, average fiber diameter 10 μm) as an inorganic fiber, 30.2% by weight of silicon carbide powder having an average particle diameter of 0.3 μm as an inorganic particle, 7% by weight of silica sol (SiO₂ content within the sol: 30% by weight) as an inorganic binder, 0.5% by weight of carboxy methylcellulose as an organic binder, and 39% by weight of water.

Afterward, using the above-mentioned sealing material paste, a sealing material paste layer having a thickness of 0.2 mm was formed over the outer circumference portion of the honeycomb block. This sealing material paste layer was then dried under a temperature of 120° C. to produce a cylindrical shaped honeycomb structure having a sealing material layer (the coat layer) of 143.8 mm in diameter×254 mm in length formed over the outer circumference.

### Example 2

The honeycomb structure was produced in a manner identical to the Example 1 aside from points of: not having had temporarily stored the honeycomb molded body after carrying out drying in the process (2) of the Example 1 and proceeding to carry out the subsequent process; after having completed the above-mentioned process (3), placing the honeycomb molded body in which the plug material paste has been filled and the drying has been carried out thereon inside of the molded body storage container using the honeycomb molded body receiving apparatus 140 shown in FIG. 3A and FIGS. 4 to 6 and thereby storing the honeycomb molded body for approximately 1 week; and taking out the honeycomb molded body that has been dried and stored using a honeycomb molded body taking-out apparatus having the same configuration as the honeycomb molded body receiving apparatus 140 and conveying to a subsequent process.

### Example 3

The honeycomb structure was produced in a manner identical to the Example 1 aside from points of: not having had temporarily stored the honeycomb molded body after carrying out drying in the process (2) of the Example 1 and thus proceeding to carry out the subsequent process; after having completed the above-mentioned process (5), placing the honeycomb molded body on which the firing treatment was carried out (honeycomb fired body) inside of the molded body storage container using the honeycomb molded body receiving apparatus 140 shown in FIG. 3A and FIGS. 4 to 6 and thereby storing the honeycomb molded body for approximately 1 week; and taking out the honeycomb fired body that has been stored using a honeycomb molded body taking-out apparatus having the same configuration as the honeycomb molded body receiving apparatus 140 and conveying to a subsequent process.

The honeycomb structure produced using the methods of the Examples 1 to 3 was one exhibiting a quality identical to that of the honeycomb structure produced according to common methods (i.e. methods carrying out continuous conveyance without temporary storage).

Obviously, numerous modifications and variations of the present invention are possible in light of the above teachings. It is therefore to be understood that within the scope of the appended claims, the invention may be practiced otherwise than as specifically described herein.

What is claimed as new and desired to be secured by Letters Patent of the United States is:

1. A method for manufacturing a honeycomb structure including a honeycomb fired body, comprising:
producing a pillar-shaped honeycomb molded body in which a plurality of cells are placed in parallel with one another in a longitudinal direction with a cell wall therebetween by molding a ceramic raw material; and
producing a honeycomb fired body by carrying out a single or a plurality of treatments including at least a firing treatment on said honeycomb molded body,
further comprising:
temporarily storing the treated honeycomb molded body on which said single or plurality of treatments have been carried out, in a molded body storage container;
taking out the treated honeycomb molded body placed in the molded body storage container from the molded body storage container; and
conveying the taken-out honeycomb molded body to a subsequent process.

2. The method for manufacturing a honeycomb structure according to claim 1,
further comprising
carrying out at least a drying treatment and the firing treatment on said honeycomb molded body after producing said honeycomb molded body,
said treated honeycomb molded body stored temporarily being the honeycomb molded body on which the drying treatment and/or the firing treatment has been carried out.

3. The method for manufacturing a honeycomb stricture according to claim 1, further comprising
carrying out at least a drying treatment, an opening-sealing treatment and the firing treatment on said honeycomb molded body after having produced said honeycomb molded body,
said treated honeycomb molded body stored temporarily being a honeycomb molded body on which at least one of the drying treatment, the opening-sealing treatment and the firing treatment has been carried out.

4. The method for manufacturing a honeycomb structure according to claim 3,
wherein
a time period of temporarily storing the honeycomb molded body on which at least one of the drying treatment, the opening-sealing treatment and the firing treatment has been carried out has been about one month.

5. A honeycomb molded body receiving apparatus used when placing a treated honeycomb molded body into a molded body storage container in the method for manufacturing a honeycomb structure according to claim 1, comprising:
a molded body pre-storage container induction portion configured to stack and hold an empty molded body storage container;
a first molded body storage container movement mechanism configured to move said empty molded body storage container in a upward/downward direction and/or a horizontal direction to situate said empty molded body storage container in a prescribed location;
a robotic arm configured to lift up and move the treated honeycomb molded body situated atop a conveyer portion using a holding portion, and place said treated honeycomb molded body inside of the empty molded body storage container situated in said prescribed location;
a second molded body storage container movement mechanism configured to stack the molded body storage container having said treated honeycomb molded body placed therein onto a molded body storage container having another treated honeycomb molded body placed therein; and
a molded body post-storage container taking-out portion configured to stack and hold the molded body storage container having said treated honeycomb molded body placed therein.

6. The honeycomb molded body receiving apparatus according to claim 5,
wherein
said treated honeycomb molded body to be temporarily stored is the honeycomb molded body on which a drying treatment and/or a firing treatment has been carried out.

7. The honeycomb molded body receiving apparatus according to claim 5,
wherein
said treated honeycomb molded body to be temporarily stored is the honeycomb molded body on which at least one of the drying treatment, an opening-sealing treatment and the firing treatment has been carried out.

8. The honeycomb molded body receiving apparatus according to claim 5,
wherein
a location where said empty molded body storage container is to be situated, when placing said treated honeycomb molded body therein, is at an upper side with respect to a location where the molded body storage container having said treated honeycomb molded body placed therein is to be stacked.

9. The honeycomb molded body receiving apparatus according to claim 5,
wherein
a location where said empty molded body storage container is to be situated, when placing said treated honeycomb molded body therein, is at an upper side with respect to a location where stacked said empty molded body storage container is held.

10. The honeycomb molded body receiving apparatus according to claim 5,
wherein
said molded body storage container has a rectangular shape when viewed from a top of said molded body storage container, and is provided with gaps on a portion of side faces corresponding to short sides thereof, in order to allow insertion of a member configured to lift up another molded body storage container stacked on the top of said molded body storage container when said molded body storage container is stacked.

11. The honeycomb molded body receiving apparatus according to claim 5, further including a storage container lifting apparatus,
wherein
said storage container lifting apparatus, disposed on both sides sandwiching a path of said molded body storage container, comprises a lifting portion configured to directly lift up the molded body storage container, an air cylinder for a purpose of moving said lifting portion in upward and downward directions, and a platform portion configured to support said air cylinder.

12. The honeycomb molded body receiving apparatus according to claim 11,
wherein
an air cylinder is disposed in said lifting portion, said air cylinder being configured in a manner enabling said lifting portion to move in a horizontal direction.

13. The honeycomb molded body receiving apparatus according to claim 5, further including a storage container support apparatus,
wherein
said storage container support apparatus, two units of which being disposed on both sides of a region through which said molded body storage container moves, comprises:
a storage container support portion which is for a purpose of supporting the molded body storage container moved thereto;
an air cylinder which is for a purpose of moving said storage container support portion in a direction nearing said molded body storage container when supporting said molded body storage container, and alternately moving said storage container support portion in a direction away from said molded body storage container when releasing said supported molded body storage container; and
a cylinder support portion configured to support said air cylinder.

14. A honeycomb molded body taking-out apparatus which is used to take out a treated honeycomb molded body from a molded body storage container in a method for manufacturing a honeycomb structure including a honeycomb fired body, the method comprising producing a pillar-shaped honeycomb molded body in which a plurality of cells are placed in parallel with one another in a longitudinal direction with a cell wall therebetween by molding a ceramic raw material; and producing a honeycomb fired body by carrying out a single or a plurality of treatments including at least a firing treatment on said honeycomb molded body, the method further comprising temporarily storing the treated honeycomb molded body on which said single or plurality of treatments have been carried out, in a molded body storage container; taking out the treated honeycomb molded body placed in the molded body storage container from the molded body storage container; and conveying the taken-out honeycomb molded body to a subsequent process, the honeycomb molded body taking-out apparatus comprising:
a molded body post-storage container induction portion configured to stack and hold the molded body storage container having said treated honeycomb molded body placed therein;
a third molded body storage container movement mechanism configured to move the molded body storage container having said treated honeycomb molded body placed therein in an upward/downward direction and/or a horizontal direction to situate said molded body storage container in a prescribed location;
a robotic arm configured to lift up and move the treated honeycomb molded body placed in said molded body storage container by using a holding portion, and place said treated honeycomb molded body atop a conveyer portion;
a fourth molded body storage container movement mechanism configured to stack the empty molded body storage container having said treated honeycomb molded body taken out therefrom onto another empty molded body storage container; and
a molded body pre-storage container taking-out portion configured to stack and hold said empty molded body storage container.

15. The honeycomb molded body taking-out apparatus according to claim 14,
wherein
said treated honeycomb molded body to be temporarily stored is the honeycomb molded body on which a drying treatment and/or a firing treatment has been carried out.

16. The honeycomb molded body taking-out apparatus according to claim 14,
wherein
said treated honeycomb molded body to be temporarily stored is the honeycomb molded body on which at least one of the drying treatment, an opening-sealing treatment and the firing treatment has been carried out.

17. The honeycomb molded body taking-out apparatus according to claim 14,
wherein
a location where said molded body storage container is to be situated, when lifting up said treated honeycomb molded body by using a holding portion, is at an upper side with respect to a location where said empty molded body storage container is to be stacked.

18. The honeycomb molded body taking-out apparatus according to claim 14,
wherein
a location where said molded body storage container is to be situated, when lifting up said treated honeycomb molded body by using a holding portion, is at an upper side with respect to a location where a stacked molded body storage container having said treated honeycomb molded body placed therein is to be held.

19. The honeycomb molded body taking-out apparatus according to claim 14,
wherein
said molded body storage container has a rectangular shape when viewed from a top of said molded body storage container, and is provided with gaps on a portion of side faces corresponding to short sides thereof, in order to allow insertion of a member configured to lift up another molded body storage container stacked on the top of said molded body storage container when said molded body storage container is stacked.

20. The honeycomb molded body taking-out apparatus according to claim 14, further including a storage container lifting apparatus,
wherein
said storage container lifting apparatus, disposed on both sides sandwiching the path of said molded body storage container, comprises a lifting portion configured to directly lift up the molded body storage container, an air cylinder for a purpose of moving said lifting portion in upward and downward directions, and a platform portion configured to support said air cylinder.

21. The honeycomb molded body receiving apparatus according to claim 14,
wherein
an air cylinder is disposed in said lifting portion, said air cylinder being configured in a manner enabling said lifting portion to move in a horizontal direction.

22. The honeycomb molded body taking-out apparatus according to claim 14, further including a storage container support apparatus,
wherein
said storage container support apparatus, two units of which being disposed on both sides of a region through which said molded body storage container moves, comprises:
a storage container support portion which is for a purpose of supporting the molded body storage container moved thereto;
an air cylinder which is for a purpose of moving said storage container support portion in a direction nearing said molded body storage container when supporting said molded body storage container, and alternately moving said storage container support portion in a direction away from said molded body storage container when releasing said supported molded body storage container; and
a cylinder support portion configured to support said air cylinder.
